(19) United States
(12) Patent Application Publication
(10) Pub. No.: US 2026/0367115 A1
(43) Pub. Date: Nov. 19, 2026

(54) CURRENT SENSOR PACKAGE STRUCTURE

(71) Applicant: Monolithic Power Systems, Inc., Kirkland, WA (US)

(72) Inventors: Kwang-Soo Kim, Sunnyvale, CA (US); Di Han, San Jose, CA (US)

(21) Appl. No.: 19/208,179

(22) Filed: May 14, 2025

(51) Int. Cl. G01R 15/20; G01R 19/00

(52) U.S. Cl. CPC G01R 15/202; G01R 19/0092

(57) ABSTRACT

A current sensor package structure includes an insulator substrate, a first conductive layer, a second conductive layer, at least one first conductive via, and a magnetic field sensor device. The first conductive layer is over a first side of the insulator substrate. The first conductive layer comprises a current conductor, the current conductor having a first portion, a second portion, and a third portion connecting the first portion to the second portion. The second conductive layer is over a second side of the insulator substrate. The second conductive layer includes a first conductive pad. The at least one first conductive via is in the insulator substrate and connecting the first portion of the current conductor to the first conductive pad. The magnetic field sensor device is over the third portion of the current conductor.

### FIELD OF INVENTION

The present application relates generally to electrical devices, and more particularly but not exclusively to current sensor package structures.

### BACKGROUND

Magnetic fields can be directly sensed using a Hall effect sensor, which can be manufactured using CMOS (complementary metal oxide semiconductor) technology. When current is flowing through a conductor, a magnetic field is generated around that conductor. The strength of the magnetic field is proportional to the current through the conductor. By placing a Hall effect sensor in the generated magnetic field, the current through the conductor can be sensed. This effect is used in Hall effect based current sensors.

A Hall effect current sensor can include additional components to determine the current information. A Hall effect current sensor can be fabricated on one die using CMOS technology. The die can include the Hall effect sensor, the timing and control units, the ADC (analog to digital converter) unit, the interfaces part and so on. The die contains electrodes for current path and I/O signal transmission with external electrical circuits.

### SUMMARY

In some embodiments of the present disclosure, a current sensor package structure includes an insulator substrate, a first conductive layer, a second conductive layer, at least one first conductive via, and a magnetic field sensor device. The insulator substrate has a first side and a second side opposite to the first side. The first conductive layer is over the first side of the insulator substrate. The first conductive layer comprises a current conductor, the current conductor having a first portion, a second portion, and a third portion connecting the first portion to the second portion. The second conductive layer is over the second side of the insulator substrate. The second conductive layer includes a first conductive pad. The at least one first conductive via is in the insulator substrate and connecting the first portion of the current conductor to the first conductive pad. The magnetic field sensor device is over the third portion of the current conductor.

In some embodiments of the present disclosure, a current sensor package structure includes an insulator substrate, a current conductor, plural conductive vias, and a magnetic field sensor device. The current conductor is over a first side of the insulator substrate, wherein the current conductor has a first portion, a second portion, and a third portion connecting the first portion to the second portion. The conductive vias extend through the insulator substrate and vertically overlapping the first portion of the current conductor. The magnetic field sensor device is over the third portion of the current conductor.

In some embodiments of the present disclosure, a current sensor package structure includes an insulator substrate, a current conductor, a magnetic field sensor device, a conductive pad, a conductive feature, and an encapsulant. The current conductor is over a first side of the insulator substrate. The current conductor has a first portion, a second portion, and a third portion connecting the first portion to the second portion. The magnetic field sensor device is over the third portion of the current conductor. The conductive pad is over a second side of the insulator substrate opposite to the first side of the insulator substrate. The conductive feature connects the first portion of the current conductor to the conductive pad. The encapsulant surrounds the insulator substrate, the current conductor, the magnetic field sensor device. A surface of the conductive pad facing away from the second side of the insulator substrate is free from coverage by the encapsulant.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic top view of a current sensor package structure in accordance with some embodiments of the present disclosure.

FIG. 1B is a schematic cross-sectional view taken along line B-B of FIG. 1A.

FIG. 1C is a schematic bottom view of the current sensor package structure of FIG. 1A.

FIG. 2 illustrates the Hall effect current sensor in the sensor device in accordance with an embodiment of the present invention.

FIG. 3A is a top view illustrating the current path in the current sensor package structure of FIG. 1A.

FIG. 3B is a schematic cross-sectional view illustrating the current path taken along line B-B of FIG. 3A.

FIG. 3C is a schematic cross-sectional view illustrating the current path taken along line C-C of FIG. 3A.

FIGS. 4-7 are schematic cross-sectional views at intermediate stages of manufacture of a current sensor package structure in accordance with some embodiments of the present disclosure.

FIG. 8A is a schematic top view of a current sensor package structure in accordance with some embodiments of the present disclosure.

FIG. 8B is a schematic cross-sectional view taken along line B-B of FIG. 7A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

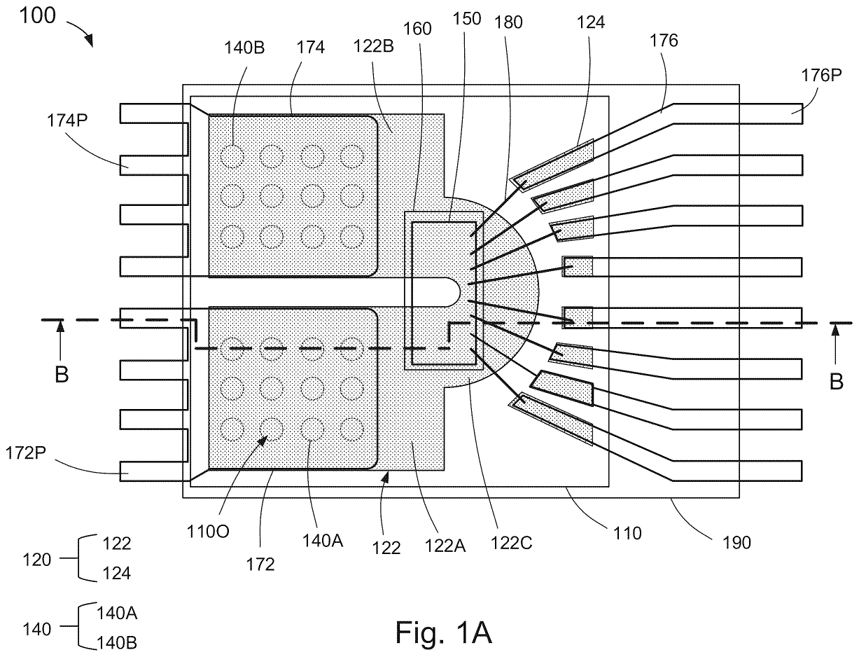

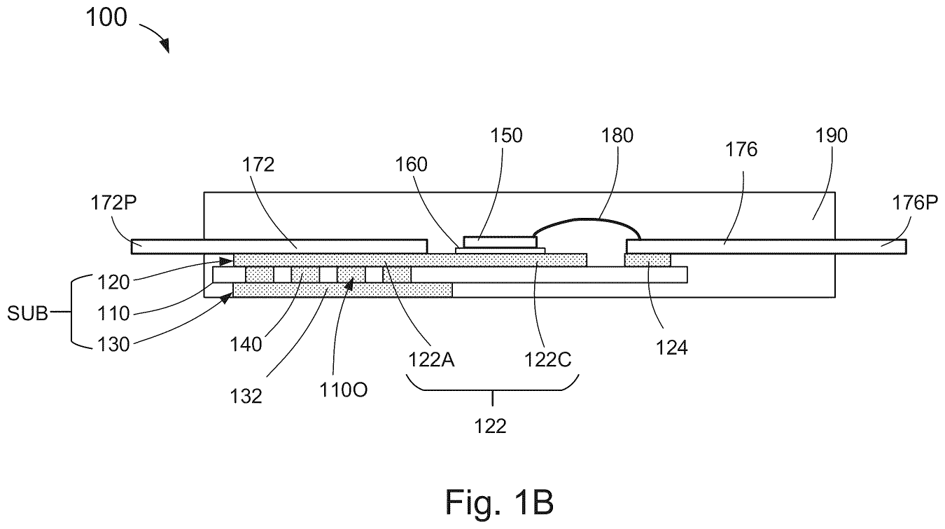

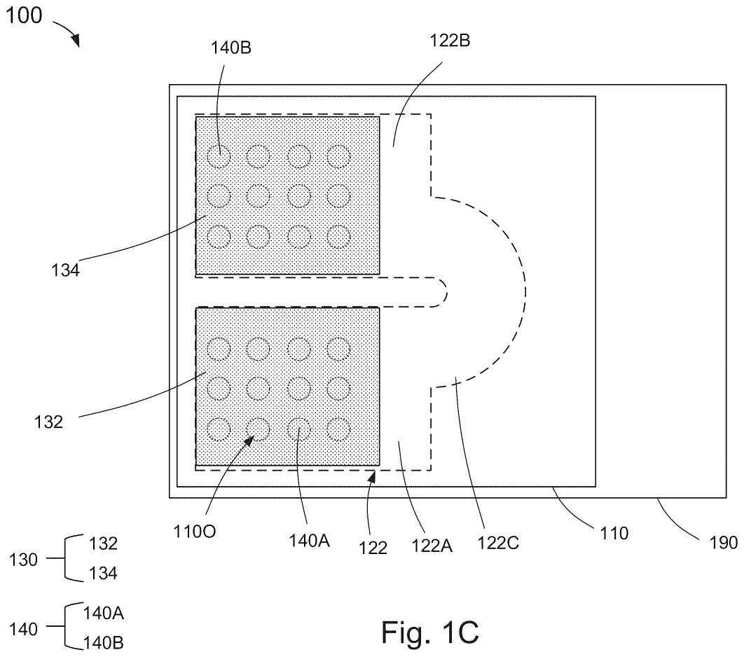

FIG. 1A is a schematic top view of a current sensor package structure 100 in accordance with some embodiments of the present disclosure. FIG. 1B is a schematic cross-sectional view taken along line B-B of FIG. 1A. FIG. 1C is a schematic bottom view of the current sensor package structure 100 of FIG. 1A. The current sensor package structure 100 includes an insulator substrate 110, first and second conductive layers 120 and 130, conductive vias 140, a sensor device 150, an isolation layer 160, lead frames 172-176, and bond wires 180, and an encapsulant 190.

The insulator substrate 110 may be made of thermal conductive electrically insulating material, such as ceramic materials (e.g., Al₂O₃, AlN, BN, SN, Si₃N₄, etc.) or other dielectric materials (e.g., polyimide, etc.). In some embodiments, the insulator substrate 110 may be a ceramic substrate. In some embodiments, the insulator substrate 110 may have a thickness in a range from about 0.1 millimeter to about 5 millimeter, such as from 0.1 millimeter to about 1 millimeter. In some embodiments, the insulator substrate 110 may be referred to as an insulator layer. The first and second conductive layers 120 and 130 are directly bonded on first and second sides of the insulator substrate 110, respectively. The first conductive layer 120 and the second conductive layer 130 may be made of electrically conductive metal or metallic materials (e.g., copper). In some embodiments, each of the first conductive layer 120 and the second conductive layer 130 may have a thickness in a range from about 0.1 millimeter to about 1 millimeter. In some embodiments, the combination of the insulator substrate 110 and the first and second conductive layers 120 and 130 may be referred to as a substrate SUB, such as a direct bonded copper (DBC) substrate.

The first conductive layer 120 is patterned into a current conductor 122 and plural lead frame bonding pads 124 spaced apart from each other. The current conductor 122 has a first portion 122A, a second portion 122B, and a current sensing portion 122C connected between the first portion 122A and the second portion 122B. The current sensing portion 122C allows a current conduction between the first portion 122A and the second portion 122B. In the present embodiments, the current sensing portion 122C has a U-shape profile having two ends connecting the first portion 112A and the second portion 112B, respectively. In some alternative embodiments, the current sensing portion 122C may have other shape, not limited to the shown U-shape profile.

The second conductive layer 130 is patterned into conductive pads 132 and 134 spaced apart from each other. In some embodiments, the conductive pads 132 and 134 are respectively directly below the first portion 122A and the second portion 122B of the current conductor 122. In some embodiments, the second conductive layer 130 (e.g., the conductive pads 132 and 134) does not vertically overlap the current sensing portion 122C of the first conductive layer 120.

In the present embodiments, the insulator substrate 110 has plural through holes 110O extending from the first side of the insulator substrate 110 to the second side of the insulator substrate 110. One or more conductive materials are formed into the through holes 110O of the insulator substrate 110, thereby forming conductive vias 140. For ease of explanation, the conductive vias 140 are annotated as conductive vias 140A and 140B. In some embodiments of the present disclosure, the conductive vias 140A are between the first portion 122A of the current conductor 122 and the conductive pad 132 therebelow, thereby electrically connecting the first portion 122A of the current conductor 122 to the conductive pad 132. And, the conductive vias 140B are between the second portion 122B of the current conductor 122 and the conductive pad 134 therebelow, thereby electrically connecting the second portion 122B of the current conductor 122 to the conductive pad 134. In some embodiments, the conductive vias 140 does not vertically overlap the current sensing portion 122C of the first conductive layer 120. Stated differently, the current sensing portion 122C of the first conductive layer 120 is free from overlapping with the conductive vias 140 in the top view.

In the present embodiments, the conductive vias 140A/140B are arranged equidistant from each other in an array in the top view. For example, the conductive vias 140A/140B may be aligned with each other in a first direction and in a second direction perpendicular to the first direction in the top view. In some alternative embodiments, the conductive vias 140A/140B can be arranged in any suitable distribution in the top view. For example, in a top view, the conductive vias 140A/140B may be aligned with each other in a first direction, and misaligned from each other in the second direction perpendicular to the first direction. In some embodiments, the conductive vias 140A/140B may be misaligned from each other in the first direction and in the second direction perpendicular to the first direction. In some other embodiments, the conductive vias 140A/140B may be in a random distribution in the top view. In the present embodiments, the space between any adjacent two of the conductive vias 140A are the same as any adjacent two of the conductive vias 140B. In some alternative embodiments, the space between any adjacent two of the conductive vias 140A may be greater or less than any adjacent two of the conductive vias 140B. In some embodiments, a distance between adjacent first and second ones of the conductive vias 140A/140B may be different from a distance between adjacent third and fourth ones of the conductive vias 140A/140B. In the present embodiments, the conductive vias 140A and 140B have substantially the same dimensions (e.g., diameters and height). In some alternative embodiments, at least two of the conductive vias 140A and 140B may have different dimensions (e.g., diameters and height). For example, the conductive vias 140A may have a diameter greater or less than that of the conductive vias 140B. The number of the conductive vias 140 (e.g., the conductive vias 140A/140B) may vary depending on device requirement. For example, the number of the conductive vias 140A/140B may be in a range from 1 to 500.

In the present embodiments, the current sensor package structure 100 is designed with conductive vias 140A and 140B and the conductive pad 132 and 134. In some other embodiments, with the configuration of the conductive vias 140A and the conductive pad 132, the conductive vias 140B and the conductive pad 134 can be omitted. In some other embodiments, with the configuration of the conductive vias 140B and the conductive pad 134, the conductive vias 140A and the conductive pad 132 can be omitted.

In the present embodiments, the portion 122A of the current conductor 122 is electrically connected to the conductive pad 132 through the conductive vias 140A, and the portion 122B of the current conductor 122 is electrically connected to the conductive pad 134 through the conductive vias 140B. In some other embodiments, other suitable conductive features (e.g., conductive blocks, conductive plates, or the like) in the insulator substrate 110 may be used to electrically connect the portion 122A of the current conductor 122 to the conductive pad 132, and/or electrically connect the portion 122B of the current conductor 122 to the conductive pad 134.

The sensor device 150 is placed over the current sensing portion 122C of the current conductor 122. The sensor device 150 can measure the current in the current sensing portion 122C of the current conductor 122 therebelow, without the need for a core. The sensor device 150 may be referred to as a sensor IC chip. For example, the sensor device 150 is a sensor die including at least one magnetic field sensor element, such as a Hall effect current sensor or a magnetoresistive (MR) sensor. For example, the magnetic field sensor element (e.g., the Hall effect current sensor or the MR sensor) can be fabricated on one sensor die using CMOS technology. The magnetic field sensor element can include additional components to determine the current information. In addition to the magnetic field sensor element (e.g., Hall effect sensor), the sensor die may further include the timing and control units, the ADC (analog to digital converter) unit, the interfaces part and so on. The sensor device 150 includes one or more contact pads facing away from the current path in the current conductor 122 for I/O signal transmission and power delivery with external electrical circuits. The one or more contact pads of the sensor device 150 are electrically connected to the lead frames 176 by bond wires 180. The bond wires 180 can be any suitable conductive wires, such as copper wires.

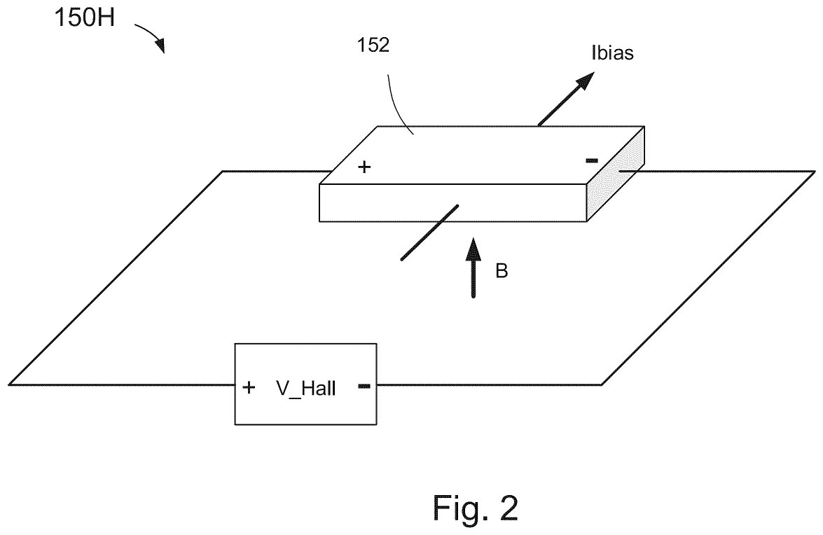

FIG. 2 illustrates the Hall effect current sensor 150H in the sensor device (e.g., the sensor device 150 in FIGS. 1A and 1B) in accordance with an embodiment of the present invention. The Hall effect current sensor 150H includes a Hall plate 152 in an IC. The Hall plate 152 may include a layer of conductive material, such as silicon (Si), gallium arsenide (GaAs), indium antimonide (InSb), or the like. When a current is flowing through a current conductor (e.g., the current sensing portion 122C of the current conductor 122 shown in FIGS. 1A and 1B), a magnetic field B is generated around that current conductor. The strength of the magnetic field B is proportional to the current through the current conductor. The magnetic field B generated by current is concentrated at the Hall plate 152. A bias voltage across the Hall plate 152 sets up a fixed current Ibias. When the magnetic field B is present, these charges experience a force, called the Lorentz force. The Lorentz force induces charge movement in the Hall plate 152, thereby pushing charges in the current Ibias to opposite sides of the Hall plate 152, which results in a Hall voltage V_Hall at the opposite sides of the Hall plate 152. The Hall voltage V_Hall is generated across the Hall plate 152, transverse to an electric current Ibias in the Hall plate 152 and a magnetic field B perpendicular to Ibias. This signal is cleaned up and amplified to provide a sensitivity in the unit of mV/A. Accordingly, by placing a Hall effect sensor in the generated magnetic field B, the current through the conductor (e.g., the current sensing portion 122C of the current conductor 122 shown in FIGS. 1A and 1B) can be sensed.

Reference is made back to FIGS. 1A and 1B. In some embodiments, the isolation layer 160 (also referred to as “the insulating layer”) is disposed between the sensor device 150 and the sensing portion 122C of the current conductor 122. In some embodiments, the isolation layer 160 provides electrical isolation between the sensor device 150 and the sensing portion 122C of the current conductor 122. In some embodiments, the isolation layer 160 includes, for example, one or more organic materials (e.g., a molding compound, bismaleimide triazine (BT), polyimide (PI), polybenzoxazole (PBO), a solder resist, an Ajinomoto build-up film (ABF), polypropylene (PP), an epoxy-based material, or a combination of two or more thereof), inorganic materials (e.g., silicon, glass, ceramic, quartz, or a combination of two or more thereof), liquid-film material(s) or dry-film material(s), or a combination of two or more thereof. In some embodiments, the isolation layer 160 may be or include an isolation tape. In some embodiments, the isolation layer 160 has a relatively high resistance that can provide sufficient electrical isolation between the sensor device 150 and the sensing portion 122C of the current conductor 122.

In the present embodiments, the lead frame 172 is bonded to the first portion 122A of the current conductor 122. The lead frame 174 is bonded to the second portion 122B of the current conductor 122. And, the lead frames 176 are respectively bonded to the lead frame bonding pads 124. In the present embodiments, the lead frame 172 overlaps all the conductive vias 140A, and the lead frame 174 overlaps all the conductive vias 140B. In some other embodiments, the lead frame 172 may overlap some of the conductive vias 140A and expose the others of the conductive vias 140A; and/or the lead frame 174 may overlap some of the conductive vias 140B and expose the others of the conductive vias 140B.

In some embodiments, the insulator substrate 110, the first and second conductive layers 120 and 130, the conductive vias 140, the sensor device 150, the isolation layer 160, portions of the lead frames 172-176, and the bond wires 180, are encapsulated in the encapsulant 190. The conductive pads 132 and 134 of the second conductive layer 130 are exposed from the encapsulant 190, in which the encapsulant 190 may be in contact with sidewalls of the conductive pads 132 and 134. The encapsulant 190 provides mechanical support for the lead frames 172-176. In the illustrated embodiments, the lead frame 172 has plural pin portions (e.g. pins 172P) extending beyond a first sidewall of the encapsulant 190, the lead frame 174 has plural pin portions (e.g., pins 174P) extending beyond the first sidewall of the encapsulant 190, and each of the lead frames 176 has a pin portion (e.g., a pin 176P) extending beyond a second sidewall of the encapsulant 190. For purposes of illustration only, the package structure 100 is shown as a 16 pin SOIC (with 8 pins being used as the current pins and 8 pins being used as the signal pins). In some other embodiments, the package structure 100 can be designed with any number of pins for establishing the current path and signal transmission.

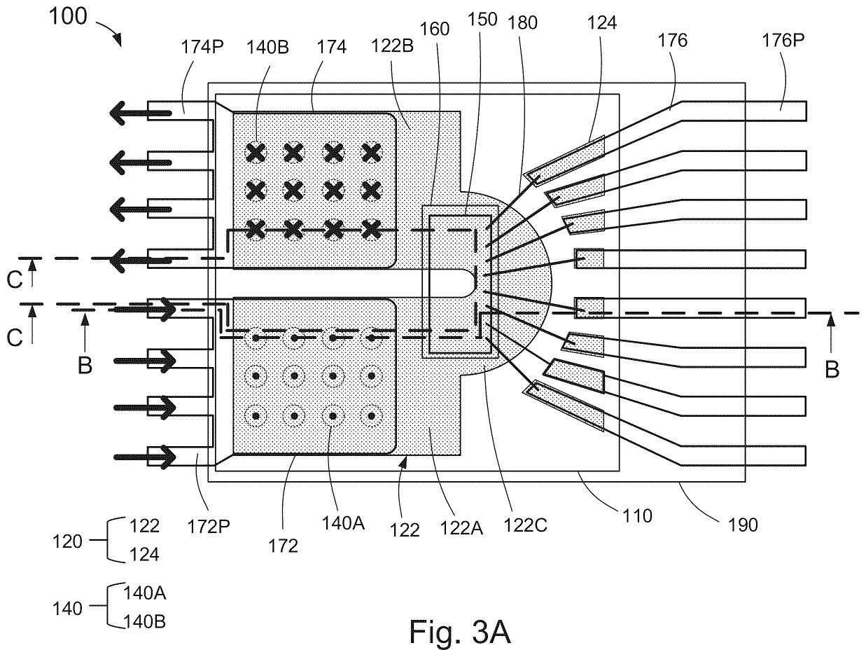

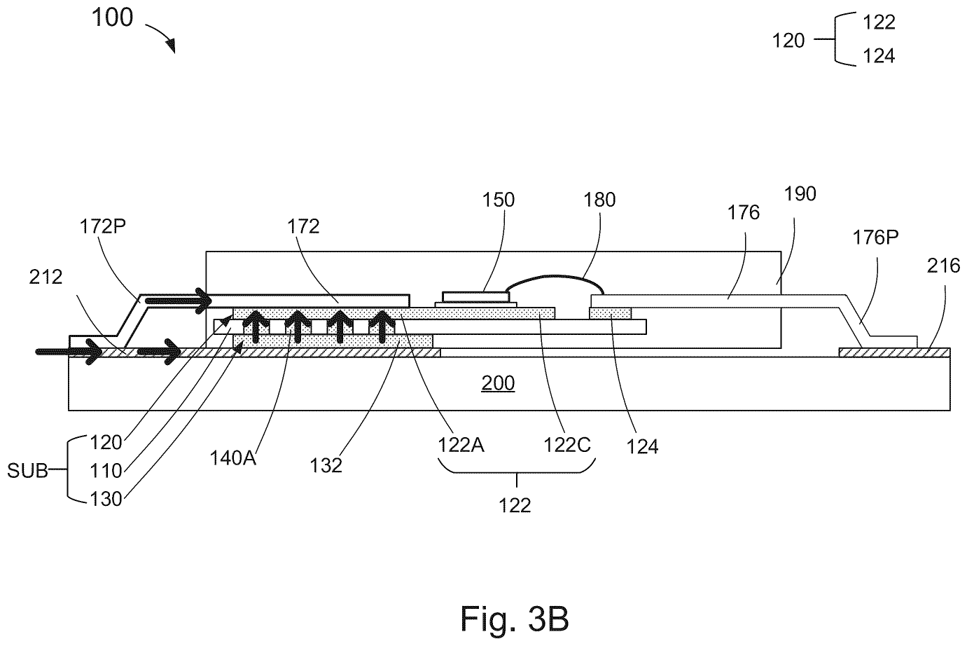

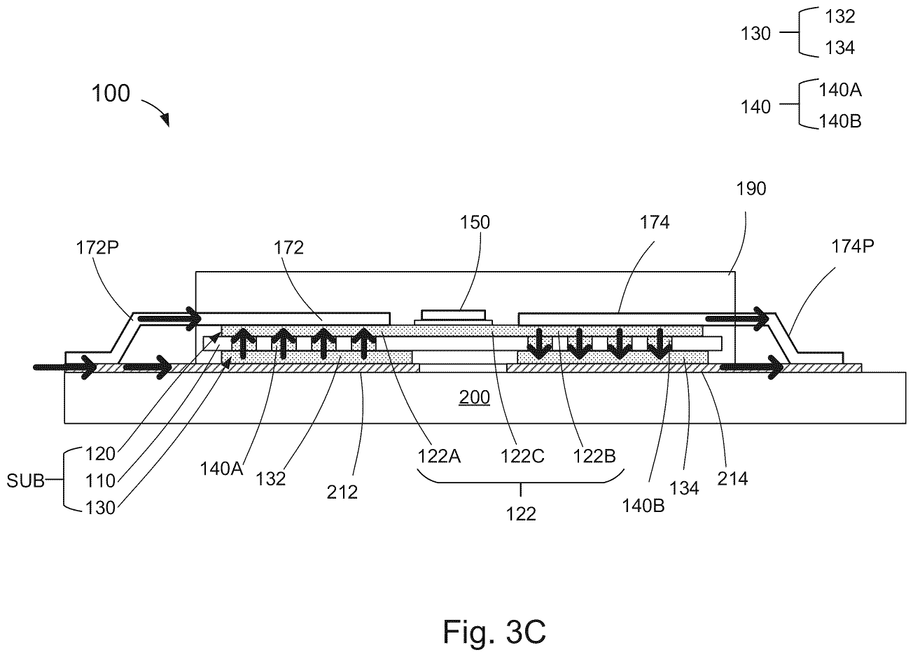

FIG. 3A is a top view illustrating the current path in the current sensor package structure of FIG. 1A. FIG. 3B is a schematic cross-sectional view illustrating the current path taken along line B-B of FIG. 3A. FIG. 3C is a schematic cross-sectional view illustrating the current path taken along line C-C of FIG. 3A. The current sensor package structure 100 is bonded on a printed circuit board 200. The printed circuit board 200 has an input current pad 212, an output current pad (not shown), and plural pads 216 on its top side facing the current sensor package structure 100. The input current pad 212, the output current pad (not shown), and the pads 216 are made of conductive materials. The lead frames 172 and the conductive pad 132 of the current sensor package structure 100 are bonded to the input current pad 212 of the printed circuit board 200. The lead frames 174 and the conductive pad 134 of the current sensor package structure 100 are bonded to the output current pad of the printed circuit board 200. And, the lead frames 176 of the current sensor package structure 100 are bonded to the pads 216 of the printed circuit board 200, respectively.

Through the configuration, a current would flow from the input current pad 212 of the printed circuit board 200 to the first portion 122A of the current conductor 122 through the lead frames 172 and the combination of the conductive pad 132 and the conductive vias 140A. The current from the first portion 122A of the current conductor 122 would go through the current sensing portion 122C of the current conductor 122 and enter the second portion 122B of the current conductor 122. The current would be sensed/measured at the current sensing portion 122C of the current conductor 122 by the sensor device 150. The sensing signal can be transmitted from the sensor device 150 to the pads 216 of the printed circuit board 200 through the lead frames 126. The current would flow from the second portion 122B of the current conductor 122 to the output current pad of the printed circuit board 200 through the lead frames 174 and the combination of the conductive pad 134 and the conductive vias 140B.

In some case, owing to the limitation of lead frame resistances, the current capability would be determined by a size of the conductor in the package. For obtaining larger current ratings (e.g., the maximum current for device is designed to carry), it is needed to increase the size of the conductor in the package for increasing the current capability, which would lead to an increase in the package size.

In the present embodiments, with configuration of the conductive vias 140A and 140B, the current can flow through the thick conductive layer 130 and the conductive vias 140A and 140B. Thus, a current capability of the package structure 100 can be increased without substantially enlarging a size of the package structure 100, and the larger current ratings can be obtained.

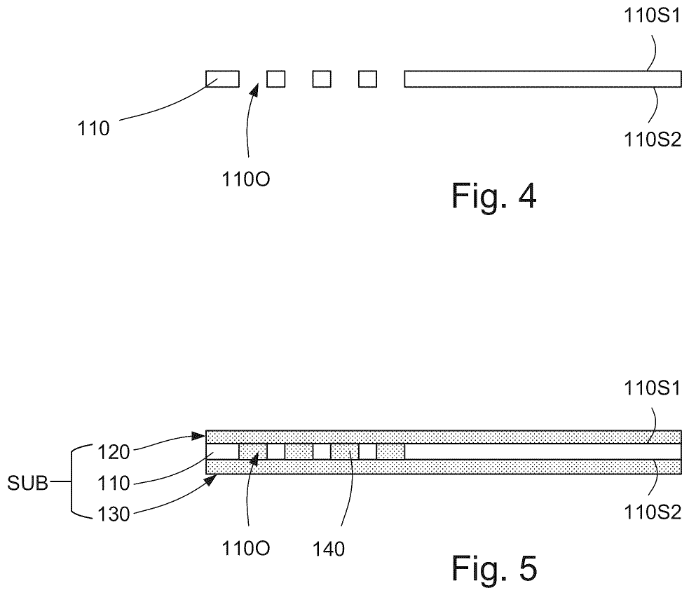

FIGS. 4-7 are schematic cross-sectional views at intermediate stages of manufacture of a current sensor package structure in accordance with some embodiments of the present disclosure. It is understood that additional steps may be provided before, during, and after the steps shown in FIGS. 4-7, and some of the steps described below can be replaced or eliminated for additional embodiments of the method. The order of the operations/processes may be interchangeable.

Reference is made to FIG. 4. The insulator substrate 110 has a first side 110S1 and a second side 110S2 opposite to the first side 110S1, in which the first side 110S1 and the second side 110S2 may be substantially flat surfaces. Through holes 110O are formed in the insulator substrate 110 from the first side 110S1 of the insulator substrate 110 to the second side 110S2 of the insulator substrate 110. The formation of the through holes 110O may include laser drilling, mechanical drilling, via etching, other via formation method, or the combination thereof. The dimension (e.g., the diameter) and the distribution of the through holes 110O can be designed according to requirement. For example, the through holes 110O may have the same or different diameters.

Reference is made to FIG. 5. A conductive material is formed into the through holes 110O, for example, by physical vapor deposition, electroplating, the like, or the combination thereof. The conductive material may be copper, the like, or the combination thereof. An excess portion of the conductive material outside of the through holes 110O may be removed, such that remaining portions of the conductive material in the through holes 110O forms the conductive vias 140. After the formation of the conductive vias 140, the first conductive layer 120 is bonded to the first side 110S1 of the insulator substrate 110; and the second conductive layer 130 is bonded to the second side 120S1 of the insulator substrate 110, for example, using a high-temperature sintering process. As aforementioned, the combination of the insulator substrate 110 and the first and second conductive layers 120 and 130 may be referred to DBC substrate SUB.

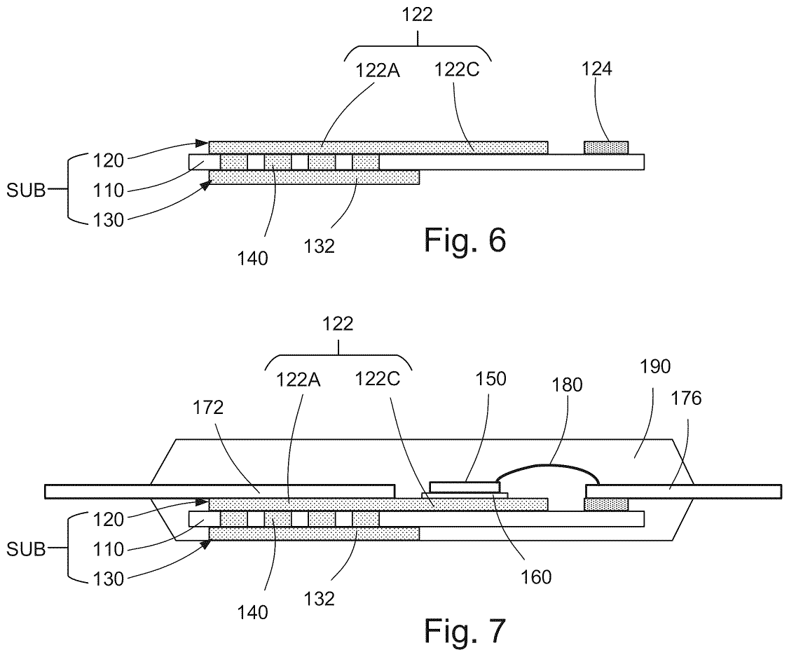

Reference is made to FIG. 6. The first conductive layer 120 is patterned into the current conductor 122 (including the portions 122A-122C in FIG. 1B) and at least one lead frame bonding pad 124 spaced apart from each other. And, the second conductive layer 130 is patterned into at least one conductive pad (e.g., the conductive pads 132 and 124 in FIG. 1B) spaced apart from each other. After being patterned, the second conductive layer 130 may be free from the portion 122C of the first conductive layer 120, thereby keeping an isolation distance for the portion 122C for the current sense function. The patterning process of each one of the first conductive layer 120 and the second conductive layer 130 may include a lithography process followed by an etching process (also referred to as a substrate etching process dry etch, wet etch, or the combination thereof). The lithography process may include photoresist coating, exposure, developing, baking, and other suitable steps. The etching process may include a dry etch, a wet etch, or the combination thereof.

Reference is made to FIG. 7. An isolation layer 160 is attached onto the portion 122C of the first conductive layer 120, and then a sensor device 150 is attached onto the isolation layer 160. In some embodiments, the lead frames 172 and 174 are bonded to the portions 122A and 122B of the first conductive layer 120, respectively, for example, by soldering. In some examples, solder layers (not shown) are disposed between the lead frames 172/174 and the portions 122A/122B of the first conductive layer 120. In some embodiments, the lead frames 176 are bonded to the lead frame bonding pads 124 of the first conductive layer 120, respectively, for example, by soldering. In some examples, solder layers (not shown) are disposed between the lead frames 176 and the lead frame bonding pads 124 of the first conductive layer 120. In some embodiments, the contact pads of the sensor device 150 are electrically connected to the lead frames 176 by wire bonding techniques. For example, first ends of the bond wires 180 are attached/bonded to the contact pads of the sensor device 150, while second ends of the bond wires 180/bonded are attached to the lead frames 176.

In some embodiments, the encapsulant 190 may be formed by applying a molding compound to surround the substrate SUB, the sensor device 150, the lead frames 172-176, and the bond wires 180, and curing the molding compound to form the encapsulant 190.

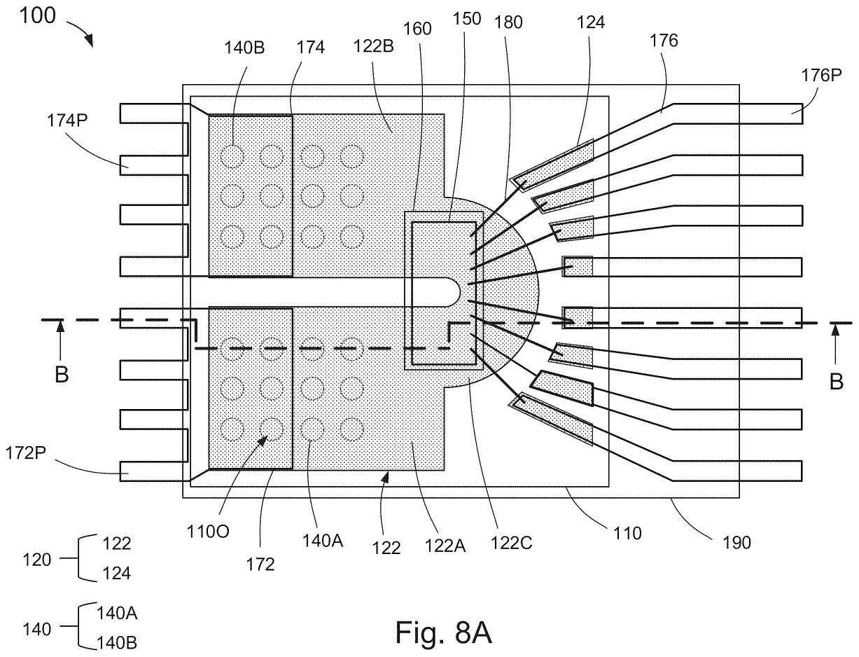

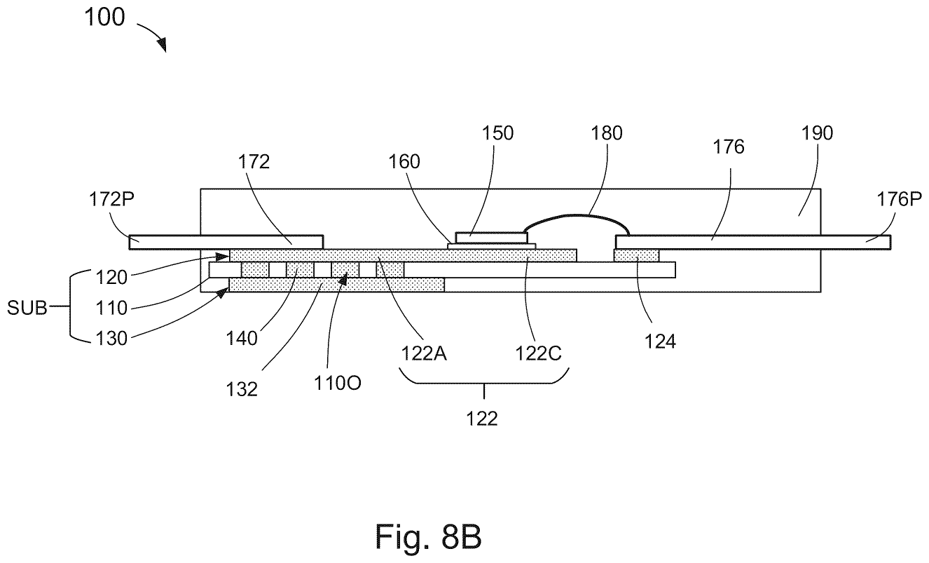

FIG. 8A is a schematic top view of a current sensor package structure 100 in accordance with some embodiments of the present disclosure. FIG. 8B is a schematic cross-sectional view taken along line B-B of FIG. 8A. Details of the present embodiments are similar to those illustrated in the embodiments of FIGS. 1A and 1B, except that the lead frame 172 may overlap some of the conductive vias 140A and expose the others of the conductive vias 140A; and/or the lead frame 174 may overlap some of the conductive vias 140B and expose the others of the conductive vias 140B. Other details of the present embodiments are similar to those illustrated above, and thereto not repeated herein.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a current capability of a current sense package structure is increased with the configuration of the conductive vias in DBC substrate. Another advantage is that larger current ratings can be obtained without substantially enlarging a size of the package structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A current sensor package structure, comprising:
an insulator substrate having a first side and a second side opposite to the first side;
a first conductive layer over the first side of the insulator substrate, wherein the first conductive layer comprises a current conductor, the current conductor having a first portion, a second portion, and a third portion connecting the first portion to the second portion;
a second conductive layer over the second side of the insulator substrate, wherein the second conductive layer comprises a first conductive pad;
at least one first conductive via in the insulator substrate and connecting the first portion of the current conductor to the first conductive pad; and
a magnetic field sensor device over the third portion of the current conductor.

2. The current sensor package structure of claim 1, wherein the first conductive pad vertically overlaps the first portion of the current conductor.

3. The current sensor package structure of claim 1, further comprising:
a first lead frame bonded to the first portion of the current conductor; and
a second lead frame bonded to the second portion of the current conductor.

4. The current sensor package structure of claim 1, wherein a plurality of the first conductive vias are in the insulator substrate and connecting the first portion of the current conductor to the first conductive pad.

5. The current sensor package structure of claim 1, wherein the second conductive layer further comprises a second conductive pad vertically overlapping the second portion of the current conductor and spaced apart from the first conductive pad.

6. The current sensor package structure of claim 5, further comprising:
at least one second conductive via in the insulator substrate and connecting the second portion of the current conductor to the second conductive pad.

7. The current sensor package structure of claim 6, wherein a plurality of the second conductive vias are in the insulator substrate and connecting the second portion of the current conductor to the second conductive pad.

8. The current sensor package structure of claim 1, wherein the second conductive layer does not vertically overlap the third portion of the current conductor.

9. The current sensor package structure of claim 1, further comprising:
a lead frame bonded to a bonding pad of the first conductive layer, wherein the lead frame is electrically connected to the magnetic field sensor device.

10. The current sensor package structure of claim 1, further comprising:
an encapsulant surrounding the insulator substrate and the magnetic field sensor device, wherein the first conductive pad is exposed from the encapsulant.

11. A current sensor package structure, comprising:
an insulator substrate;
a current conductor over a first side of the insulator substrate, wherein the current conductor has a first portion, a second portion, and a third portion connecting the first portion to the second portion;
a plurality of conductive vias extending through the insulator substrate and vertically overlapping the first portion of the current conductor; and
a magnetic field sensor device over the third portion of the current conductor.

12. The current sensor package structure of claim 11, further comprising:
a first lead frame bonded to the first portion of the current conductor; and
a second lead frame bonded to the second portion of the current conductor.

13. The current sensor package structure of claim 12, wherein the first lead frame overlaps the conductive vias in a top view.

14. The current sensor package structure of claim 12, wherein the first lead frame overlaps a first portion of the conductive vias in a top view, and a second portion of the conductive vias are free from overlapping with the first lead frame in a top view.

15. The current sensor package structure of claim 11, further comprising:
a conductive pad over a second side of the insulator substrate opposite to the first side of the insulator substrate, wherein the conductive pad vertically overlaps the conductive vias.

16. A current sensor package structure, comprising:
an insulator substrate;
a current conductor over a first side of the insulator substrate, wherein the current conductor has a first portion, a second portion, and a third portion connecting the first portion to the second portion;
a magnetic field sensor device over the third portion of the current conductor.
a conductive pad over a second side of the insulator substrate opposite to the first side of the insulator substrate;
a conductive feature connecting the first portion of the current conductor to the conductive pad; and
an encapsulant surrounding the insulator substrate, the current conductor, the magnetic field sensor device, wherein a surface of the conductive pad facing away from the second side of the insulator substrate is free from coverage by the encapsulant.

17. The current sensor package structure of claim 16, wherein the conductive feature is surrounded by the insulator substrate.

18. The current sensor package structure of claim 16, further comprising:
a first lead frame bonded to the first portion of the current conductor and extending beyond a sidewall of the encapsulant; and
a second lead frame bonded to the second portion of the current conductor away and extending beyond the sidewall of the encapsulant.

19. The current sensor package structure of claim 16, wherein the third portion of the current conductor is free from overlapping with the conductive feature in a top view.

20. The current sensor package structure of claim 16, wherein the encapsulant is in contact with a sidewall of the conductive pad.
